(19) United States
(12) Patent Application Publication
(10) Pub. No.: US 2015/0102330 A1
(43) Pub. Date: Apr. 16, 2015

(54) COMPOSITION AND DEVICE

(71) Applicant: Sumitomo Chemical Company Limited, Tokyo (JP)

(72) Inventors: Julian Carter, Cambridge (GB); Nicholas Dartnell, Cambridgeshire (GB)

(73) Assignee: Sumitomo Chemical Co. Limited, Tokyo (JP)

(21) Appl. No.: 14/513,425

(22) Filed: Oct. 14, 2014

(30) Foreign Application Priority Data
Oct. 14, 2013 (GB) GB1318151.6

(51) Int. Cl. H01L 51/00; H01L 51/56; H01L 51/50

(52) U.S. Cl. CPC H01L 51/004; H01L 51/5028; H01L 51/56; H01L 51/0043; H01L 51/0035; H01L 51/0085
USPC 257/40; 438/46; 252/500

(57) ABSTRACT

A composition comprises a low molecular weight polyelectrolyte, a high molecular weight polymer, a light-emitting material and a salt. The viscosity average molecular weight of the high molecular weight polymer in at least one solvent is at least 5 times greater than the viscosity average molecular weight of the low molecular weight polyelectrolyte in the at least one solvent, and the high molecular weight polymer and the low molecular weight polymer are preferably different molecular weight polymers of the same polyelectrolyte material, such as polyethylene oxide. The composition is used to provide a light emitting layer (103) in a light-emitting electrochemical cell between an anode (101) for injecting positive charge carriers and a cathode (105) for injecting negative charge carriers.

### RELATED APPLICATIONS

This Application claims priority to Great Britain Patent Application No. 1318151.6, filed on Oct. 14, 2013, the entirety of which is incorporated herein by reference.

### BACKGROUND

Electronic devices comprising active organic materials are attracting increasing attention for use in devices such as organic light emitting diodes, organic photoresponsive devices (in particular organic photovoltaic devices and organic photosensors), organic transistors and memory array devices. Devices comprising organic materials offer benefits such as low weight, low power consumption and flexibility. Moreover, use of soluble organic materials allows use of solution processing in device manufacture, for example inkjet printing or spin-coating.

An organic light-emitting electrochemical cell (LEC) may have a substrate carrying an anode, a cathode and an organic light-emitting layer between the anode and cathode comprising a light-emitting material, a salt providing mobile ions and an electrolyte, for example a polymer electrolyte (“polyelectrolyte”). LECs are disclosed in, for example, WO 96/00983.

During operation of the device, holes are injected into the device through the anode and electrons are injected through the cathode. Holes in the highest occupied molecular orbital (HOMO) and electrons in the lowest unoccupied molecular orbital (LUMO) of the light-emitting material combine in the light-emitting layer to form an exciton that releases its energy as light. The cations and anions of the salt may respectively p- and n-dope the light-emitting material, which may provide for a low drive voltage.

Suitable light-emitting materials include small molecule, polymeric and dendrimeric materials. Suitable light-emitting polymers for use in the light-emitting layer include poly(arylene vinylenes) such as poly(p-phenylene vinylenes) and polyarylenes such as polyfluorenes.

U.S. Pat. No. 5,900,327 discloses a LEC comprising the polymer BDOH-PF:

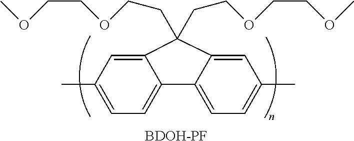

The ethylene oxide side groups of BDOH-PF are said to improve compatibility with the ion-conducting polymer poly(ethylene oxide) and increase solubility of the polymer in common organic solvents.

The light-emitting layer of a LEC may be formed by depositing an ink containing the materials of the light-emitting layer and a solvent followed by evaporation of the solvent.

WO 2011/032010 discloses luminescent ink formulations containing a plurality of salts providing at least two cations or two anions.

WO 2003/053707 discloses screen-printable light-emitting polymer based inks containing a non-electroluminescent polymer with a molecular weight between about 300,000 and 20,000,000 to provide a viscosity of above about 50 centipoises. Use of polyethylene oxide (PEO) is described as an acceptable non-electroluminescent polymer.

One problem with formation of a light-emitting layer from an ink is that the components of the light-emitting layer may be drawn to the perimeter of the deposited ink during evaporation of the solvent, resulting in a light-emitting film in which materials of the film are concentrated at a film perimeter (the “coffee-ring” effect). This can cause poor uniformity of emission from the device and lead to potential device yield issues.

WO 02/069119 discloses inks for formation of a light-emitting layer of an OLED, comprising a solvent system including a combination of a relatively high boiling point solvent and a relatively low boiling point solvent to reduce the coffee-ring effect.

It is an object of the invention to provide LECs having uniform light-emitting film thickness.

It is a yet further object of the invention to provide a method of forming light-emitting films of a LEC suitable for a broad range of printing or coating techniques.

### SUMMARY OF THE INVENTION

In a first aspect, the invention provides a light-emitting composition comprising a low molecular weight polyelectrolyte, a high molecular weight polymer, a light-emitting material and a salt, wherein the viscosity average molecular weight of the high molecular weight polymer in at least one solvent is at least 5 times greater than the viscosity average molecular weight of the low molecular weight polyelectrolyte in the at least one solvent.

Optionally, the viscosity average molecular weight of the high molecular weight polymer is at least 10 times greater than the viscosity average molecular weight of the low molecular weight polyelectrolyte.

In a second aspect, the invention provides a method of preparation of a composition according to the first aspect of the invention, comprising the step of mixing the high molecular weight polymer with the low molecular weight polyelectrolyte.

In a third aspect, the invention provides a composition obtainable by the method according to second aspect of the invention.

In a fourth aspect, the invention provides a formulation comprising a composition according to the first or according to the third aspect of the invention, and the at least one solvent.

In a fifth aspect, the invention provides a light-emitting electrochemical cell comprising an anode for injecting positive charge carriers, a cathode for injecting negative charge carriers and a light-emitting layer between the anode and the cathode, wherein the light-emitting layer comprises a composition according to the first or third aspect of the invention.

In a sixth aspect the invention provides a method of forming a light-emitting electrochemical cell according to the fifth aspect of the invention, the method comprising the steps of:
(i) depositing the formulation according to the fourth aspect over one of the anode and cathode;
(ii) evaporating the at least one solvent; and
(iii) forming the other of the anode and cathode over the light-emitting layer.

In a seventh aspect the invention provides a light-emitting composition comprising a polyelectrolyte, a light-emitting material, a polymer comprising dialkylsiloxane repeat units and a salt.

The polyelectrolyte according to the seventh aspect may be a poly(ethylene oxide) as described anywhere herein. The composition of the seventh aspect may comprise a mixture of polyelectrolytes as described anywhere herein. The salt and the light-emitting polymer according to the seventh aspect may be as described anywhere herein. The composition of the seventh aspect may be used to form a light-emitting electrochemical cell as described anywhere herein.

Viscosity average molecular weight Mv of a polymer is given by:

$${M}_{v} = {[ \frac{{\sum }_{i} {N}_{i} {M}_{i}^{1 + a}}{{\sum }_{i} {N}_{i} {M}_{i}} ]}^{\frac{1}{a}}$$

where N is the number of moles in a sample of the polymer having mass M, N*M is the mass of the sample, and a is the exponent in the Mark-Houwink equation that relates the intrinsic viscosity to molar mass.

The viscosity average molecular weights of the high and low molecular weight polymers may be as measured in a single solvent or a mixture of two or more solvent.

### DESCRIPTION OF THE DRAWINGS

The invention will now be described in more detail with reference to the drawings in which:

FIG. 1 illustrates an organic LEC according to an embodiment of the invention;

FIG. 2A illustrates a partial LEC structure of an LEC according to an embodiment of the invention wherein the anode of the LEC is patterned in a desired emission shape;

FIG. 2B illustrates a partial LEC structure of an LEC according to an embodiment of the invention wherein the anode is patterned to form a plurality of individual pixel anodes and a light-emitting film is formed over each pixel anode;

FIG. 2C illustrates a partial LEC structure of an LEC according to an embodiment of the invention wherein the anode is patterned to form a plurality of individual pixel anodes and the light-emitting layer is formed from a plurality of light-emitting films wherein each light-emitting film extends over a plurality of pixel anodes;

FIG. 3 is a graph illustrating the thickness variation across a central axis of a printed area obtained with a Comparative Ink Formulation comprising a single polyelectrolyte component and an Example Ink Formulation according to an embodiment of the invention; and

FIG. 4 is a graph illustrating the viscosity of Example Ink Formulations according to embodiments of the invention containing various amounts of PEO polyelectrolyte with molecular weight of 5M and 8M.

### DETAILED DESCRIPTION OF THE INVENTION

FIG. 1 illustrates an organic LEC 100 according to an embodiment of the invention. The cell 100 has an anode 101, for example ITO, a metal or a conductive organic material such as a polythiophene, for injection of positive charge carriers, a cathode 105 for injection of negative charge carriers and a light-emitting layer 103 between the anode and the cathode. Further layers may be provided between the anode and the cathode, for example a hole-injection layer may be provided between the anode 101 and the light-emitting layer 103. The cell is supported on a substrate 107. If light is emitted through the anode then the substrate 107 is a transparent material, for example glass or a transparent plastic. If light is emitted through the cathode 105 then the substrate 107 may be an opaque or transparent material.

The light-emitting layer contains at least one light emitting material, a polyelectrolyte having a relatively low molecular weight, a relatively high molecular weight polymer and at least one salt. Preferably, the relatively high molecular weight polymer is a polyelectrolyte. The low and high molecular weight polymers may be different molecular weight polymers of the same polyelectrolyte material.

In operation, light may be emitted directly from the one or more light-emitting polymers, or a light-emitting dopant may be provided in the light-emitting layer. The light-emitting dopant may be a fluorescent dopant that accepts singlet excitons from the light-emitting polymer wherein fluorescence is produced by radiative decay of singlet excitons, or a phosphorescent dopant that accepts triplet excitons, and optionally singlet excitons, from the light-emitting polymer and emits light by radiative decay of triplet excitons.

If a light-emitting dopant is present then all light may be emitted by the dopant, or both the light-emitting polymer and the light-emitting dopant may emit light. More than one light-emitting dopant may be present. Light-emission from multiple light-emitting materials (either polymers or dopants) may combine to produce white light.

The light-emitting layer may have a thickness in the range of about 100 nm-2 microns, preferably 100 nm-1 micron; preferably 100 nm-750 nm, preferably 100-500 nm.

The light-emitting layer 103 illustrated in FIG. 1 is a film that extends across the whole of the surface area of the anode 101 and cathode 105, however in other embodiments the light-emitting layer 103 may comprise two or more separate light-emitting films. The light-emitting film or films of a light-emitting layer may have a width of up to about 2 cm, optionally up to about 1 cm, up to about 5 mm. The light-emitting film or films may have a width of at least 0.5 mm.

The anode and/or cathode may be patterned.

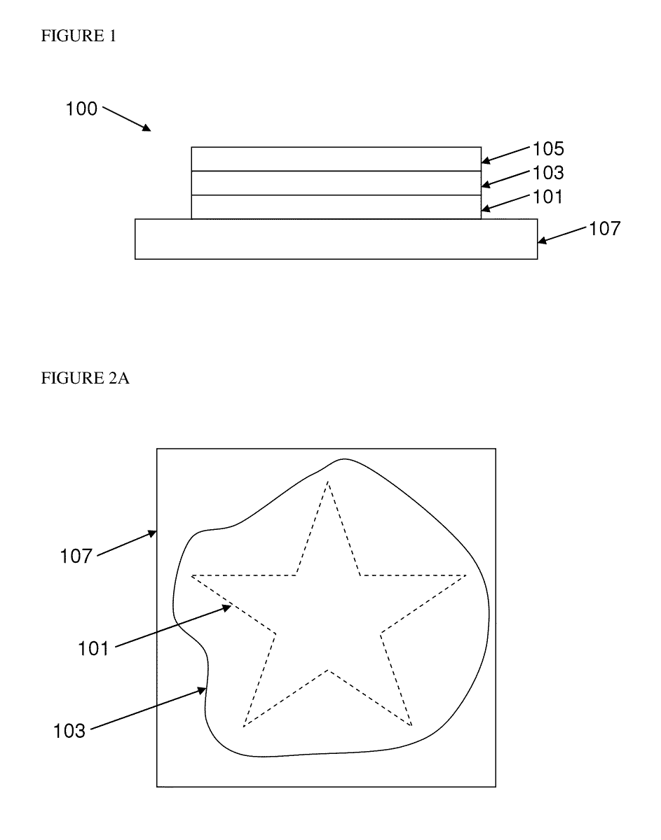

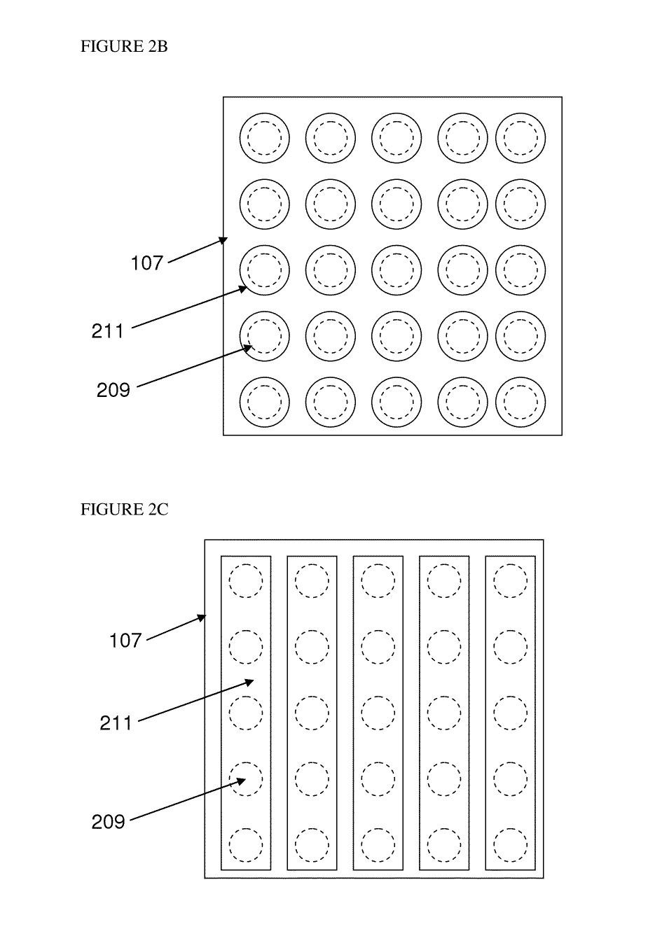

FIG. 2A schematically illustrates a plan view of a partial LEC structure of a LEC according to an embodiment of the invention in which the anode 101 is patterned in a desired shape (in this case a star) and the light-emitting layer 103 is a film extending across the whole of the patterned anode area. The cathode 105 (not shown) also extends across the whole of the patterned anode area. In operation of the device, the emitted light corresponds to the patterned anode shape. In other embodiments, the light-emitting layer 103 and/or cathode 105 may be patterned in a desired emission shape and the anode 101 may be patterned or unpatterned.

FIG. 2B schematically illustrates a plan view of a partial LEC structure of a LEC according to another embodiment of the invention in which the anode 101 is patterned to form a plurality of individually addressable pixel anodes 209. A light-emitting film 211 is formed over each pixel anode 209 to provide a light-emitting layer 103 comprising a plurality of separate light-emitting films. The cathode (not shown) may extend across the area of all of the pixel anodes 209 and light-emitting films 211. In another embodiment (not shown), a LEC may have a plurality of individually addressable pixel cathodes and an anode extending across the area of all of the pixel cathodes.

FIG. 2C schematically illustrates a plan view of a partial LEC structure of a LEC according to another embodiment of the invention, with a similar structure to the device of FIG. 2B except that each light-emitting film extends across a plurality of patterned anodes 101.

In a further embodiment (not shown) the anode 101 and cathode 105 may be in the form of intersecting (e.g. perpendicular) stripes, with pixels being formed at the intersection of anode and cathode stripes. In this embodiment the light-emitting layer may extend over the whole of the anode and/or cathode area, or may be provided in the form of a plurality of films wherein each film extends across an anode or cathode stripe area.

The light-emitting layer is formed by depositing a formulation comprising the components of the light-emitting layer and at least one solvent, and evaporating the at least one solvent.

The composition contains both a low molecular weight polyelectrolyte and a high molecular weight material, preferably a high molecular weight polyelectrolyte. The relatively high viscosity of the high molecular weight polyelectrolyte may limit or prevent movement of the components of the light-emitting layer during solvent evaporation, preventing a “coffee-ring” effect wherein the dried layer is substantially thicker at its edges than at its centre.

### Polymer Electrolyte

Exemplary polymer electrolytes include: polyalkylene oxides, for example polyethylene oxide (PEO) and polypropylene oxides; copolymers of alkylene oxide, for example polyethylene-block(ethylene glycol) polymer and poly(ethylene glycol)-block-poly(propylene glycol)-block poly(ethylene glycol) polymer; esters of polyalkyleneglycols such as polycarbonates; polyolefins; and polysiloxanes.

A polyalkylene oxide polymer electrolyte may carry hydroxyl end-capping groups.

The low molecular weight polymer electrolyte may have a viscosity average molecular weight of up to 1,000,000, optionally up to 500,000 Da. The low molecular weight polymer electrolyte may have a viscosity average molecular weight of at least 1,000 Da or at least 50,000 Da. Optionally, the low molecular weight polymer electrolyte may have a viscosity average molecular weight in the range of about 50,000-500,000 Da.

The high molecular weight polymer, for example a high molecular weight polyelectrolyte, may have a viscosity average molecular weight of more than 1,000,000 Da, optionally at least 1,500,000 or 2,000,000 Da or at least 5,000,000. The high molecular weight polymer may have a viscosity average molecular weight of up to about 20,000,000, optionally up to about 10,000,000.

The weight average weight of the high molecular weight polymer may be 5 times, 10 times or 20 times greater than that of the low molecular weight polyelectrolyte.

The high molecular weight polymer and low molecular weight polymer electrolyte together may make up at least 1 weight %, 2 weight %, 5 weight %, optionally at least 10 weight % of the composition, and are optionally provided in an amount of up to 20 weight % or up to 30 weight %.

The high molecular weight polymer:low molecular weight polymer electrolyte weight ratio may be in the range of about 1:99, 5:95 or 10:90 up to about 20:80, 30:70 or 40:60.

The light-emitting material or materials of the composition may make up at least 50 weight % of the composition, and may form up to 80 or 90 weight % of the composition. In the case of a host/dopant system, the weight of the light-emitting materials includes the weight of the host material.

The weight percentages of components of the composition provided herein are the weight percentages of the components of the light-emitting layer following evaporation of the solvent(s).

### Salts

Salts with relatively small anions or cations may be more mobile than salts with bulkier ions.

Preferred cations of the salt include alkali, alkali earth and ammonium cations. Ammonium cations include NH₄⁺ cations and mono-, di-tri and tetraalkylammonium cations.

Preferred anions of the salt include halogen-containing anions, in particular fluorine-containing anions, for example hexafluorophosphate and tetrafluoroborate.

The light-emitting composition may include only one salt or more than one salt. The ionic salt or salts may be provided in an amount in the range 0.1-25% by weight, optionally 1-15% by weight, of the composition.

### Light-Emitting Material

The light-emitting material may be a small molecule or polymeric material.

Suitable light-emitting polymers include homopolymers or copolymers comprising two or more different repeat units.

A light-emitting polymer may have a backbone containing repeat units that are conjugated to adjacent repeat units, or may contain a substantially non-conjugated backbone with conjugated groups pendant from the non-conjugated backbone.

An exemplary polymer with a non-conjugated backbone is poly(vinylcarbazole).

Exemplary polymers with at least partially conjugated backbones include polymers containing arylene, heteroarylene, arylenevinylene or heteroarylenevinylene repeat units in the polymer backbone, wherein said arylene, heteroarylene, arylenevinylene or heteroarylenevinylene repeat units may be substituted or unsubstituted, for example substituted with one or more hydrocarbyl groups, for example one or more C₁₋₄₀ hydrocarbyl groups, wherein one or more non-adjacent carbon atoms in a carbon chain of the hydrocarbyl groups may be replaced with O. Exemplary C₁₋₄₀ hydrocarbyl groups include C₁₋₂₀ alkyl groups and phenyl substituted with one or more C₁₋₁₀ alkyl groups.

If used in the same layer as, or in a layer adjacent to, a light-emitting material with a high singlet or triplet energy level then the extent of conjugation along the backbone of the polymer may be limited by selection of repeat units. Exemplary repeat units that may limit the extent of conjugation include:
(i) repeat units that are twisted out of the plane of adjacent repeat units, limiting the extent of p-orbital overlap between adjacent repeat units;
(ii) conjugation-breaking repeat units that do not provide a conjugation path between repeat units adjacent to the conjugation breaking repeat units; and
(iii) repeat units that are linked to adjacent repeat units through positions that limit the extent of conjugation between repeat units adjacent to the repeat unit.

One preferred class of arylene repeat units is phenylene repeat units, such as phenylene repeat units of formula (III):

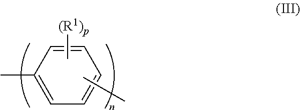

wherein p in each occurrence is independently 0, 1, 2, 3 or 4, optionally 1 or 2; n is 1, 2 or 3; and R¹ independently in each occurrence is a substituent.

Where present, each R¹ may independently be selected from the group consisting of:
alkyl, optionally C₁₋₂₀ alkyl, wherein one or more non-adjacent C atoms may be replaced with optionally substituted aryl or heteroaryl, O, S, substituted N, C═O or —COO—, and one or more H atoms may be replaced with F;
aryl and heteroaryl groups that may be unsubstituted or substituted with one or more substituents, preferably phenyl substituted with one or more C₁₋₂₀ alkyl groups; and
a linear or branched chain of aryl or heteroaryl groups, each of which groups may independently be substituted, for example a group of formula —(Ar³)ᵣ wherein each Ar³ is independently an aryl or heteroaryl group and r is at least 2, preferably a branched or linear chain of phenyl groups each of which may be unsubstituted or substituted with one or more C₁₋₂₀ alkyl groups.

Substituted N, where present, may be —NR²— wherein R² is C₁₋₂₀ alkyl; unsubstituted phenyl; or phenyl substituted with one or more C₁₋₂₀ alkyl groups.

One or more substituents R¹ may be polar substituents. Polar substituents R¹ may improve compatibility of the light-emitting polymer with polymer electrolytes such as polyethylene oxide.

Polar substituents R¹ include substituents having the following formula (X):

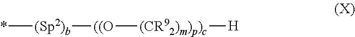

wherein * represents a point of attachment of the substituent to the repeat unit; Sp² is a spacer group; b is 0 or 1; c is at least 1, optionally 1, 2 or 3; m independently in each occurrence is at least 1, optionally 1, 2 or 3; p is at least 1, optionally 1, 2 or 3; and R⁹ in each occurrence is independently H or a substituent, preferably H or C₁₋₅ alkyl.

Sp² is preferably a C₁₋₁₀ hydrocarbyl group, preferably unsubstituted phenyl or phenyl substituted with one or more C₁₋₁₀ alkyl groups.

Polar substituents R¹ may contain one or more polar oligo-ether groups, for example substituents containing one or more polar groups —(OCH₂CH₂)_{w}—R⁸ wherein w is at least 1, optionally 1-5, and R⁸ is H or a substituent, optionally H, C₁₋₁₀ alkyl or C₁₋₁₀ alkoxy.

Preferably, each R¹ is independently selected from C₁₋₄₀ hydrocarbyl wherein one or more non-aromatic C atoms in a chain of the hydrocarbyl group may be replaced with O, and is more preferably selected from C₁₋₂₀ alkyl wherein one or more non-adjacent C atoms may be replaced with O; unsubstituted phenyl; and phenyl substituted with one or more C₁₋₂₀ alkyl groups wherein one or more non-adjacent C atoms of the alkyl group or groups may be replaced with O.

A further class of arylene repeat units are optionally substituted fluorene repeat units, such as repeat units of formula (IV):

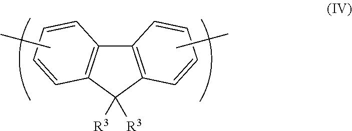

wherein R³ in each occurrence is the same or different and is H or a substituent, and wherein the two groups R³ may be linked to form a ring.

Each R³ is preferably a substituent, and each R³ may independently be selected from the group consisting of:
alkyl, optionally C₁₋₂₀ alkyl, wherein one or more non-adjacent C atoms may be replaced with optionally substituted aryl or heteroaryl, O, S, substituted N, C═O or —COO—, and one or more H atoms may be replaced with F;
aryl or heteroaryl that may be unsubstituted or substituted with one or more substituents; and
a linear or branched chain of aryl or heteroaryl groups, each of which groups may independently be substituted, for example a group of formula —(Ar³)ᵣ as described above with reference to formula (III).

In the case where R³ comprises an aryl or heteroaryl group, or a linear or branched chain of aryl or heteroaryl groups, the or each aryl or heteroaryl group may be substituted with one or more substituents R⁴ selected from the group consisting of:
alkyl, for example C₁₋₂₀ alkyl, wherein one or more non-adjacent C atoms may be replaced with O, S, substituted N, C═O and —COO— and one or more H atoms of the alkyl group may be replaced with F;
NR⁵₂, OR⁵, SR⁵, and
fluorine, nitro and cyano;
   wherein each R⁵ is independently selected from the group consisting of alkyl, preferably C₁₋₂₀ alkyl; and aryl or heteroaryl, preferably phenyl, optionally substituted with one or more C₁₋₂₀ alkyl groups.

The aromatic carbon atoms of the fluorene repeat unit may be unsubstituted, or may be substituted with one or more substituents. Exemplary substituents are alkyl, for example C₁₋₂₀ alkyl, wherein one or more non-adjacent C atoms may be replaced with O, S, NH or substituted N, C═O and —COO—, optionally substituted aryl, optionally substituted heteroaryl, alkoxy, alkylthio, fluorine, cyano and arylalkyl. Particularly preferred substituents include C₁₋₂₀ alkyl and substituted or unsubstituted aryl, for example phenyl. Optional substituents for the aryl include one or more C₁₋₂₀ alkyl groups.

Substituted N, where present, may be —NR²— wherein R² is C₁₋₂₀ alkyl; unsubstituted phenyl; or phenyl substituted with one or more C₁₋₂₀ alkyl groups.

One or more substituents R³ may be polar substituents. Polar substituents R³ may improve compatibility of the light-emitting polymer with polymer electrolytes such as polyethylene oxide. Polar substituents R³ may contain one or more polar oligo-ether groups, for example substituents containing one or more polar groups —(OCH₂CH₂)_{w}—R⁸ as described above with reference to formula (III).

Preferably, each R³ is independently selected from C₁₋₄₀ hydrocarbyl wherein one or more non-aromatic C atoms in a chain of the hydrocarbyl group may be replaced with O, and is more preferably selected from: C₁₋₂₀ alkyl wherein one or more non-adjacent C atoms may be replaced with O; unsubstituted phenyl; and phenyl substituted with one or more C₁₋₂₀ alkyl groups wherein one or more non-adjacent C atoms of the alkyl group or groups may be replaced with O.

The repeat unit of formula (IV) may be a 2,7-linked repeat unit of formula (IVa):

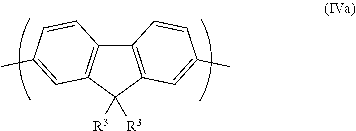

Optionally, the repeat unit of formula (IVa) is not substituted in a position adjacent to the 2- or 7-positions.

The extent of conjugation of repeat units of formulae (IV) may be limited by (a) linking the repeat unit through the 3- and/or 6-positions to limit the extent of conjugation across the repeat unit, and/or (b) substituting the repeat unit with one or more further substituents R¹ in or more positions adjacent to the linking positions in order to create a twist with the adjacent repeat unit or units, for example a 2,7-linked fluorene carrying a C₁₋₂₀ alkyl substituent in one or both of the 3- and 6-positions.

The light-emitting polymer may contain repeat units carrying polar substituents, for example substituents of formula *-(Sp²)_{b}-((O—(CR⁹₂)ₘ)ₚ)_{c}—H or —(OCH₂CH₂)_{w}—R⁸ as described with reference to formula (X), and repeat units carrying non-polar substituents, for example C₁₋₄₀ hydrocarbyl substituents. For example, a light-emitting polymer may contain repeat units of formula (IV) having polar substituents such as substituents of formula *-(Sp²)_{b}—((O—(CR⁹₂)ₘ)ₚ)_{c}—H or —(OCH₂CH₂)_{w}—R⁸ and repeat units of formula (IV) having non-polar substituents such as C₁₋₄₀ hydrocarbyl.

The polymer may contain amine repeat units in particular amines of formula (IX):

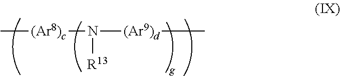

wherein Ar⁸ and Ar⁹ in each occurrence are independently selected from substituted or unsubstituted aryl or heteroaryl, g is greater than or equal to 1, preferably 1 or 2, R¹³ is H or a substituent, preferably a substituent, and c and d are each independently 1, 2 or 3.

R¹³, which may be the same or different in each occurrence when g>1, is preferably selected from the group consisting of alkyl, for example C₁₋₂₀ alkyl, Ar¹⁰, or a branched or linear chain of Ar¹⁰ groups, wherein Ar¹⁰ in each occurrence is independently optionally substituted aryl or heteroaryl. Exemplary spacer groups are C₁₋₂₀ alkyl, phenyl and phenyl-C₁₋₂₀ alkyl.

Any of Ar⁸, Ar⁹ and, if present, Ar¹⁰ bound directly to a N atom in the repeat unit of Formula (IX) may be linked by a direct bond or a divalent linking atom or group to another of Ar⁸, Ar⁹ and Ar¹⁰ bound directly to the same N atom. Preferred divalent linking atoms and groups include O, S; substituted N; and substituted C.

Any of Ar⁸, Ar⁹ and, if present, Ar¹⁰ may be substituted with one or more substituents. Exemplary substituents are substituents R¹⁴, wherein each R¹⁴ may independently be selected from the group consisting of substituted or unsubstituted alkyl, optionally C₁₋₂₀ alkyl, wherein one or more non-adjacent C atoms may be replaced with optionally substituted aryl or heteroaryl, O, S, substituted N, C═O or —COO— and one or more H atoms may be replaced with F.

Substituted N or substituted C, where present, may be N or C substituted with a hydrocarbyl group (in the case of substituted N) or two hydrocarbyl groups (in the case of substituted C), for example a C₁₋₁₀ alkyl, unsubstituted phenyl or phenyl substituted with one or more C₁₋₁₀ alkyl groups.

Preferred repeat units of formula (IX) have formulae 1-3:

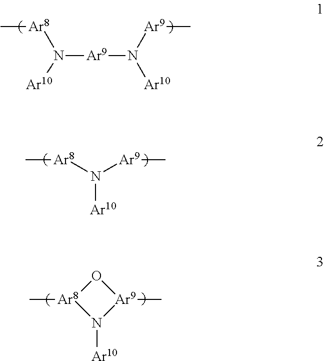

In one preferred arrangement, R¹³ is Ar¹⁰ and each of Ar⁸, Ar⁹ and Ar¹⁰ are independently unsubstituted or substituted with one or more C₁₋₂₀ alkyl groups.

Ar⁸, Ar⁹ and Ar¹⁰ are preferably phenyl, each of which may independently be substituted with one or more substituents as described above.

In another preferred arrangement, Ar⁸ and Ar⁹ are phenyl, each of which may be substituted with one or more C₁₋₂₀ alkyl groups, and R¹³ is 3,5-diphenylbenzene wherein each phenyl may be substituted with one or more C₁₋₂₀ alkyl groups.

In another preferred arrangement, c, d and g are each 1 and Ar⁸ and Ar⁹ are phenyl linked by an oxygen atom to form a phenoxazine ring.

Amine repeat units may be provided in a molar amount in the range of about 0.5 mol % up to about 50 mol %, optionally up to 40 mol %.

The light-emitting layer may contain a host material and a light-emitting dopant. Exemplary host materials include materials that are capable of emitting light in the absence of a light-emitting dopant, for example a light-emitting polymer as described above.

The light-emitting polymer may comprise conjugation-breaking repeat units that break any conjugation path between repeat units adjacent to the conjugation-breaking repeat unit. An exemplary conjugation-breaking repeat unit has formula (I):

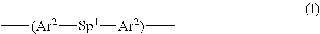

wherein Ar² in each occurrence independently represents a substituted or unsubstituted aryl or heteroaryl group; Sp¹ represents a spacer group that does not provide any conjugation path between the two groups Ar².

Ar² is preferably phenyl that may be unsubstituted or substituted with one or more substituents, preferably one or more C₁₋₂₀ alkyl groups.

Sp¹ may contain a single non-conjugating atom only between the two groups Ar², or Sp¹ may contain non-conjugating chain of at least 2 atoms separating the two groups Ar².

A non-conjugating atom may be, for example, —O—, —S—, —CR⁷₂— or —SiR⁷₂— wherein R⁷ in each occurrence is H or a substituent, optionally C₁₋₂₀ alkyl.

A spacer chain Sp¹ may contain two or more atoms separating the two groups Ar², for example a C₁₋₂₀ alkyl chain wherein one or more non-adjacent C atoms of the chain may be replaced with O or S. Preferably, the spacer chain Sp¹ contains at least one sp³-hybridised carbon atom separating the two groups Ar².

Preferred groups Sp¹ are selected from C₁₋₂₀ alkyl wherein one or more non-adjacent C atoms may be replaced with O. An ether spacer or oligo-ether spacer chain, for example a chain of formula —(CH₂CH₂O)ᵥ—, wherein v is 1 or more, optionally 1-10, may improve miscibility of the light-emitting polymer with electrolytes such as poly(ethylene oxide).

Examples of cyclic non-conjugating spacers are optionally substituted cyclohexane or adamantane repeat units that may have the structures illustrated below:

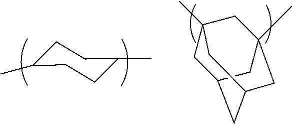

Exemplary substituents for cyclic conjugation repeat units include C₁₋₁₀ alkyl. Conjugation breaking repeat units may make up 0.5-30 mol % of repeat units of a polymer, preferably 1-20 mol % of repeat units.

The light-emitting polymer may have a weight average molecular weight in the range of about 100,000-1,000,000, optionally 100,000-500,000 as measured by GPC calibrated against polystyrene standards.

A formulation of one or more salts, a polymer electrolyte, a light-emitting polymer and (if present) one or more dopants may contain 40-97, optionally 50-95 weight % of the light-emitting polymer.

Suitable dopants include fluorescent dopants and phosphorescent dopants. Fluorescent dopants suitably have an lowest excited state singlet energy level that is no higher than, and optionally lower than, that of the host material such that singlet excitons may be transferred from the light-emitting material to the dopant. Phosphorescent dopants suitably have an lowest excited state triplet energy level that is no higher than, and optionally lower than, that of the host material such that triplet excitons may be transferred from the light-emitting material to the dopant.

### Phosphorescent Light-Emitting Materials

Exemplary phosphorescent light-emitting materials include metal complexes comprising substituted or unsubstituted complexes of formula (II):

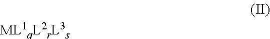

wherein M is a metal; each of L¹, L² and L³ is a coordinating group; q is an integer; r and s are each independently 0 or an integer; and the sum of (a·q)+(b·r)+(c·s) is equal to the number of coordination sites available on M, wherein a is the number of coordination sites on L¹, b is the number of coordination sites on L² and c is the number of coordination sites on L³.

Heavy elements M induce strong spin-orbit coupling to allow rapid intersystem crossing and emission from triplet or higher states. Suitable heavy metals M include d-block metals, in particular those in rows 2 and 3 i.e. elements 39 to 48 and 72 to 80, in particular ruthenium, rhodium, palladium, rhenium, osmium, iridium, platinum and gold. Iridium is particularly preferred.

Exemplary ligands L¹, L² and L³ include carbon or nitrogen donors such as porphyrin or bidentate ligands of formula (III):

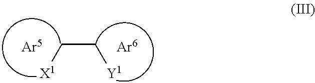

wherein Ar⁵ and Ar⁶ may be the same or different and are independently selected from substituted or unsubstituted aryl or heteroaryl; X¹ and Y¹ may be the same or different and are independently selected from carbon or nitrogen; and Ar⁵ and Ar⁶ may be fused together. Ligands wherein X¹ is carbon and Y¹ is nitrogen are preferred, in particular ligands in which Ar⁵ is a single ring or fused heteroaromatic of N and C atoms only, for example pyridyl or isoquinoline, and Ar⁶ is a single ring or fused aromatic, for example phenyl or naphthyl.

Examples of bidentate ligands are illustrated below:

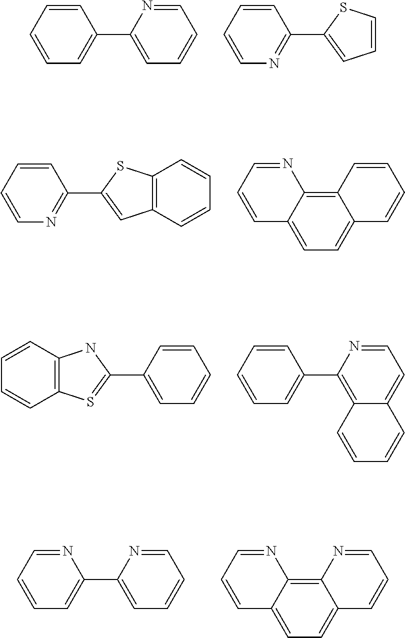

Other ligands suitable for use with d-block elements include diketonates, in particular acetylacetonate (acac); triarylphosphines and pyridine, each of which may be substituted.

Each of Ar⁵ and Ar⁶ may carry one or more substituents. Two or more of these substituents may be linked to form a ring, for example an aromatic ring.

Exemplary substituents of ligands of formula (III) include groups R³ as described above with reference to Formula (IV), preferably C₁₋₄₀ hydrocarbyl. Particularly preferred substituents include fluorine or trifluoromethyl which may be used to blue-shift the emission of the complex, for example as disclosed in WO 02/45466, WO 02/44189, US 2002-117662 and US 2002-182441; alkyl or alkoxy groups, for example C₁₋₂₀ alkyl or alkoxy, which may be as disclosed in JP 2002-324679; carbazole which may be used to assist hole transport to the complex when used as an emissive material, for example as disclosed in WO 02/81448; bromine, chlorine or iodine which can serve to functionalise the ligand for attachment of further groups, for example as disclosed in WO 02/68435 and EP 1245659; and dendrons which may be used to obtain or enhance solution processability of the metal complex, for example as disclosed in WO 02/66552.

A light-emitting dendrimer comprises a light-emitting core, such as a metal complex of formula (II), bound to one or more dendrons, wherein each dendron comprises a branching point and two or more dendritic branches. Preferably, the dendron is at least partially conjugated, and at least one of the branching points and dendritic branches comprises an aryl or heteroaryl group, for example a phenyl group. In one arrangement, the branching point group and the branching groups are all phenyl, and each phenyl may independently be substituted with one or more substituents, for example alkyl or alkoxy.

A dendron may have optionally substituted formula (IV)

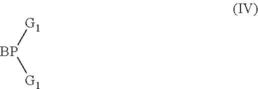

wherein BP represents a branching point for attachment to a core and G₁ represents first generation branching groups.

The dendron may be a first, second, third or higher generation dendron. G₁ may be substituted with two or more second generation branching groups G₂, and so on, as in optionally substituted formula (IVa):

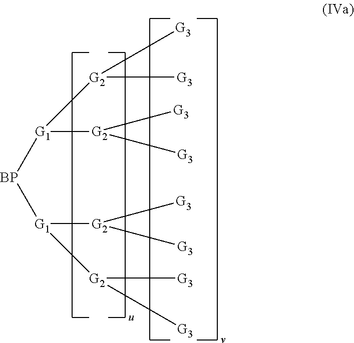

wherein u is 0 or 1; v is 0 if u is 0 or may be 0 or 1 if u is 1; BP represents a branching point for attachment to a core and G₁, G₂ and G₃ represent first, second and third generation dendron branching groups. In one preferred embodiment, each of BP and G₁, G₂ . . . Gₙ is phenyl, and each phenyl BP, G₁, G₂ . . . Gₙ₋₁ is a 3,5-linked phenyl.

A preferred dendron is a substituted or unsubstituted dendron of formula (IVb):

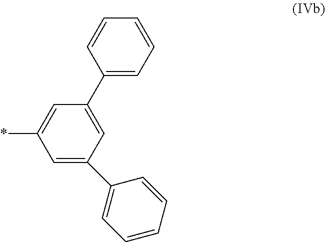 [SMILES: *c1cc(-c2ccccc2)cc(-c2ccccc2)c1]

wherein * represents an attachment point of the dendron to a core.

BP and/or any group G may be substituted with one or more substituents, for example one or more C₁₋₂₀ alkyl or alkoxy groups.

Phosphorescent light-emitting materials of a light-emitting composition may be present in an amount of about 0.05 mol % up to about 20 mol %, optionally about 0.1-10 mol % relative to their host material. A light-emitting composition may contain one or more phosphorescent light-emitting materials.

A phosphorescent material be physically mixed with the light-emitting material as host or may be chemically bound to the light-emitting material. In the case of a polymeric light-emitting host, the phosphorescent material may be provided in a side-chain, main chain or end-group of the polymer. Where a phosphorescent material is provided in a polymer side-chain, the phosphorescent material may be directly bound to the backbone of the polymer or spaced apart therefrom by a spacer group, for example a C₁₋₂₀ alkyl spacer group in which one or more non-adjacent C atoms may be replaced by O or S or —C(═O)O—.

### White Light Emission

In the case of a white light-emitting LEC or composition, the light emitted may have CIE x coordinate equivalent to that emitted by a black body at a temperature in the range of 2500-9000K and a CIE y coordinate within 0.05 or 0.025 of the CIE y co-ordinate of said light emitted by a black body, optionally a CIE x coordinate equivalent to that emitted by a black body at a temperature in the range of 2700-4500K.

### Formulations

An ink formulation suitable for forming a light-emitting layer may be formulated by mixing the components of the composition with one or more suitable solvents.

Optionally, more than one solvent is used wherein the light-emitting polymer is soluble in at least one of the solvents and wherein the polymer electrolyte is soluble in at least one of the other solvents.

Solvents suitable for dissolving light-emitting polymers, particularly polymers comprising alkyl substituents, include benzenes substituted with one or more C₁₋₁₀ alkyl or C₁₋₁₀ alkoxy groups, for example toluene, xylenes and methylanisoles.

Solvents suitable for dissolving polymer electrolytes, for example PEO, include benzenes substituted with polar groups, for example electron-withdrawing groups, such as groups with a positive Hammett constant. Suitable polar groups include chlorine, cyano, C₁₋₁₀ alkoxy and benzoate substituents. Exemplary solvents include chlorobenzene.

The formulation may be a solution in which all components of the composition are dissolved in the solvent or solvents, or it may be a dispersion wherein one or more components of the composition are suspended in the formulation. Preferably, the formulation is a solution.

Optionally, the low molecular weight polyelectrolyte, a high molecular weight polymer, the light-emitting material and salt together form 0.2-10 weight % of the formulation, optionally 0.5-3 weight % of the formulation.

The formulation may contain further components such as surfactants and/or compatibilisers. Suitable compatibilisers include polymers comprising dialkylsiloxane repeat units, for example a dimethylsiloxane-ethylene oxide copolymer.

### Deposition Methods

Ink formulations as described above may be deposited by a wide variety of coating and printing methods known to the skilled person including, without limitation, spin-coating, dip-coating, bar-coating, doctor blade coating, screen printing, gravure printing, inkjet printing, nozzle printing, nozzle printing and slot die coating.

Nozzle printing, gravure printing and screen printing are preferred methods. In the method of nozzle printing onto a surface, the ink formulation may be ejected from a nozzle in a continuous stream (as opposed to ejection of individual droplets of the ink formulation). The ink dispensed in a nozzle printing process may be in simultaneous contact with both the nozzle tip and the deposition surface. Nozzle printing may produce lines of printed ink formulation that dries into corresponding lines of light-emitting films, or adjacent lines may coalesce to form a single film whilst still fluid.

Preferably, no structures for containment of the formulation are provided on the surface that the formulation is deposited onto, such as a photoresist defining wells, channels or other structures for containment of the formulation.

The viscosity of ink formulations as described herein may be selected according to the deposition method used.

In the case of nozzle printing, a preferred viscosity range of the ink is in the range of 2-70 cP, optionally 4 cP to 50 cP, optionally 5-20 cP.

In the case of gravure printing a preferred viscosity range of the ink is in the range of 5-300 cP, optionally 10-100 cP, optionally 10-50 cP.

Viscosities as described herein are as measured at a shear rate of 1000/s at 20° C. using a cone and plate rheometer.

Following deposition, solvent may be allowed to evaporate from the formulation at ambient pressure and temperature or may be heated and/or placed under vacuum.

### Hole Injection Layers

A conductive hole injection layer, which may be formed from a conductive organic or inorganic material, may be provided between the anode and the light-emitting layer of an LEC to improve hole injection from the anode into the light-emitting layer. Examples of doped organic hole injection materials include optionally substituted, doped poly(ethylene dioxythiophene) (PEDT), in particular PEDT doped with a charge-balancing polyacid such as polystyrene sulfonate (PSS) as disclosed in EP 0901176 and EP 0947123, polyacrylic acid or a fluorinated sulfonic acid, for example Nafion®; polyaniline as disclosed in U.S. Pat. No. 5,723,873 and U.S. Pat. No. 5,798,170; and optionally substituted polythiophene or poly(thienothiophene). Examples of conductive inorganic materials include transition metal oxides such as VOx MoOx and RuOx as disclosed in Journal of Physics D: Applied Physics (1996), 29(11), 2750-2753.

### Cathode

The cathode may consist of a single material such as a layer of aluminium or silver. Alternatively, it may comprise a plurality of layers, for example a bilayer of metals such as calcium and aluminium as disclosed in WO 98/10621, or elemental barium, either alone or with one or more cathode layers, for example a bilayer of barium and aluminium as disclosed in WO 98/57381, Appl. Phys. Lett. 2002, 81(4), 634 and WO 02/84759. The cathode may contain a thin layer (e.g. of about 0.5-5 nm) of metal compound, in particular an oxide or fluoride of an alkali or alkali earth metal between the light-emitting layer and one or more conductive layers (e.g. one or more metal layers) to assist electron injection, for example lithium fluoride as disclosed in WO 00/48258; barium fluoride as disclosed in Appl. Phys. Lett. 2001, 79(5), 2001; and barium oxide.

The cathode may be in direct contact with the light-emitting layer.

The cathode may be an air-stable conductive material, for example a metal, optionally aluminium or silver. The cathode may be deposited by evaporation or sputtering, or by deposition of a paste of the metal. A paste of the metal may be deposited by a printing method, for example screen printing.

The cathode may be opaque or transparent. Transparent cathodes are particularly advantageous for active matrix devices because emission through a transparent anode in such devices is at least partially blocked by drive circuitry located underneath the emissive pixels. A transparent cathode comprises a layer of an electron injecting material that is sufficiently thin to be transparent. Typically, the lateral conductivity of this layer will be low as a result of its thinness. In this case, the layer of electron injecting material is used in combination with a thicker layer of transparent conducting material such as indium tin oxide.

It will be appreciated that a transparent cathode device need not have a transparent anode (unless, of course, a fully transparent device is desired), and so the transparent anode used for bottom-emitting devices may be replaced or supplemented with a layer of reflective material such as a layer of aluminium. Examples of transparent cathode devices are disclosed in, for example, GB 2348316.

### Encapsulation

Organic optoelectronic devices tend to be sensitive to moisture and oxygen.

Accordingly, the substrate preferably has good barrier properties for prevention of ingress of moisture and oxygen into the device. The substrate is commonly glass, however alternative substrates may be used, in particular where flexibility of the device is desirable. For example, the substrate may comprise one or more plastic layers, for example a substrate of alternating plastic and dielectric barrier layers or a laminate of thin glass and plastic.

The device may be encapsulated with an encapsulant (not shown) to prevent ingress of moisture and oxygen. Suitable encapsulants include a sheet of glass, films having suitable barrier properties such as silicon dioxide, silicon monoxide, silicon nitride or alternating stacks of polymer and dielectric or an airtight container. In the case of a transparent cathode device, a transparent encapsulating layer such as silicon monoxide or silicon dioxide may be deposited to micron levels of thickness, although in one preferred embodiment the thickness of such a layer is in the range of 20-300 nm. A getter material for absorption of any residual moisture or any atmospheric moisture and/or oxygen that may permeate through the substrate or encapsulant may be disposed between the substrate and the encapsulant.

### EXAMPLES

### Example 1

Ink formulations used for comparing the impact of a high molecular weight additive on printed film uniformity are presented in Table 1.

Comparative Ink Formulation 1 and Example Ink Formulation 1 containing the components in the amounts given in Table 1 were prepared by dissolving a light-emitting polymer, 300K Mv polymer electrolyte and salts in a solvent mixture of 4-methylanisole and 1,3 dimethoxybenzene. In the Example Ink Formulations a portion of the 300K PEO electrolyte has been replaced by 5M or 8M Mv PEO.

TABLE 1
Comparative and Example Ink Formulations

| | Weight percentage (Wt %) | |
|---|---|---|
| Material | Comparative Formulation | Example Formulation |
| Formulation | 1 | 1 |
| LEP | 1.6 | 1.6 |
| PEO 300K | 0.27 | 0.216 |
| PEO 5M or 8M | — | 0.054 |
| DBE-821 | 0.14 | 0.14 |
| THA⁺PF6⁻ | 0.08 | 0.08 |
| THP⁺BF4⁻ | 0.053 | 0.053 |
| 4-methylanisole | 48.9 | 48.9 |
| 1,3 dimethoxybenzene | 48.9 | 48.9 |

THA⁺PF6⁻ is tetrahexylammonium hexafluorophosphate.
THP⁺BF4⁻ is trihexyltetradecylphophonium tetrafluoroborate.
DBE-821 is dimethylsiloxane-ethylene oxide block copolymer available from Gelest, Inc. and used as a compatibiliser.
300K, 5M or 8M Mv Polyethylene oxide is available from Sigma-Aldrich.
LEP is a light-emitting polymer having a fluorescent polymer backbone and phosphorescent end-capping groups wherein the polymer is formed by Suzuki polymerisation as described in WO 00/53656 of the following monomers:

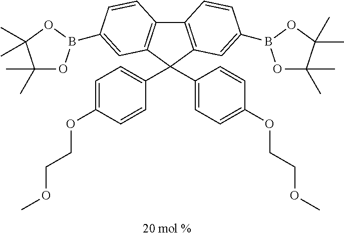

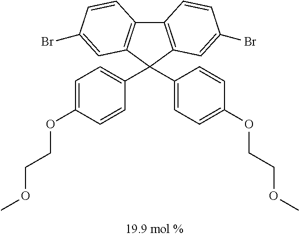

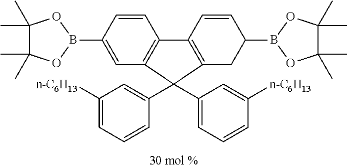

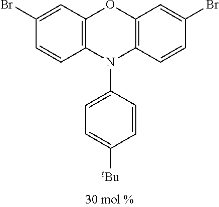 [SMILES: CC(C)(C)c1ccc(N2c3ccc(Br)cc3Oc3cc(Br)ccc32)cc1]

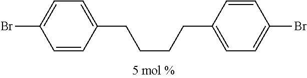 [SMILES: Brc1ccc(CCCCc2ccc(Br)cc2)cc1]

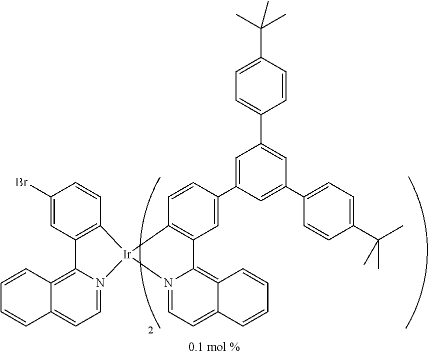

A glass substrate carrying two ITO pixel electrodes was cleaned with acetone and isopropyl alcohol, treated with UV light and ozone, and blown with nitrogen gas. Formulation Example 1, containing 300,000 Mv PEO and 5,000,000 Mv PEO, was deposited onto the glass substrate and over the pixel electrodes by nozzle printing in a spiral pattern. The lines of the spiral pattern coalesced and dried to form a film having an area of about 2×3 cm extending over the pixel electrodes. A Dektak profilometer was used to measure the thickness of the film across regularly made scratches in the coating, either across the two pixel areas or across the entire film. For the purpose of comparison, Comparative Example 1 was prepared in the same way but using a formulation in which the only PEO present had a Mv of 300,000.

Table 2 shows the result of evaluating these data either across the two pixel active areas on the substrate or across the entire printed pattern. It can be seen that the addition of the additive with high molecular weight in the Example Ink Formulation results in a reduced thickness variation.

TABLE 2
Film thickness evaluation

| | | Whole area | | Pixel area | |
|---|---|---|---|---|---|
| Comparative | Average | 1247 nm | | 1100 nm | |
| Example 1 | thickness | | | | |
| | Standard | 400 nm | 32.1% | 112 nm | 10.2% |
| | deviation | | | | |
| | Spread | 2376 nm | 190.6% | 368 nm | 33.5% |
| Example 1 | Average | 1264 nm | | 1086 nm | |
| | thickness | | | | |
| | Standard | 259 nm | 20.5% | 55 nm | 5.1% |
| | deviation | | | | |
| | Spread | 991 nm | 78.4% | 179 nm | 16.5% |

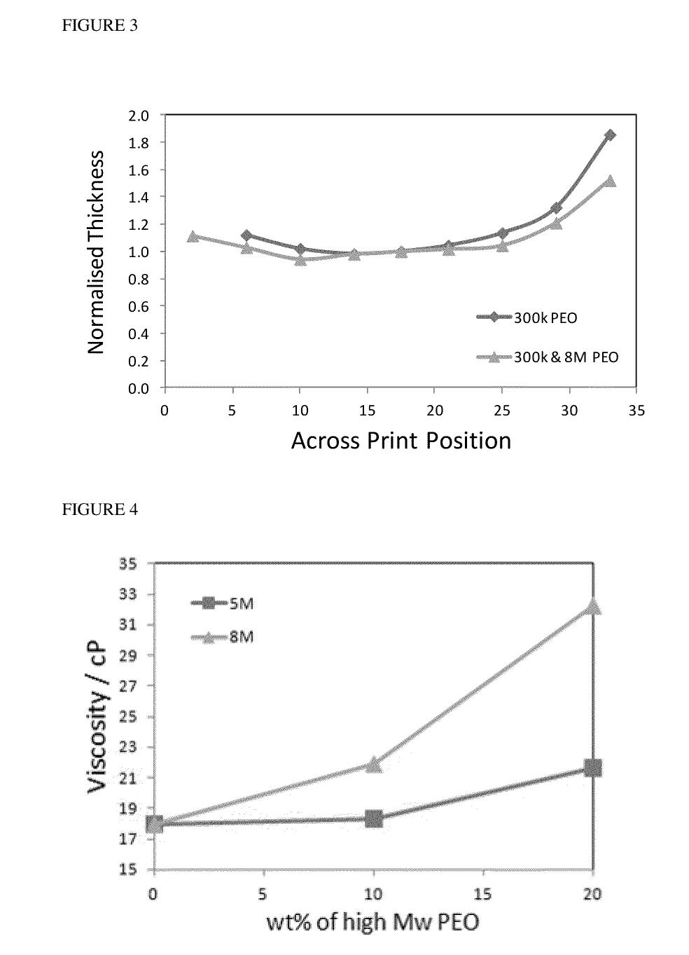

FIG. 3 shows a comparison of the normalised thickness variations along a central long axis for plates formed with Comparative Ink Formulation 1 containing only the lower molecular weight PEO of 300K versus the Example Ink Formulation 1 containing 80% of the low molecular weight 300K PEO and 20% of the 8M high molecular weight PEO. It can be seen that the addition of a higher Mv polyelectrolyte leads to a reduced thickness variation. As can be seen from FIG. 3, there is a direct correlation between the ink viscosity and the amount of the added high molecular weight electrolyte in the formulation (wt % of high Mw PEO) used at 5M or 8M. Viscosity increases with molecular weight of the high molecular weight PEO.

Without wishing to be bound by any theory, it is believed that an increase in viscosity of a formulation by introduction of the high molecular weight material may prevent or limit movement of materials in the formulation during drying of the formulation, thereby reducing non-uniformity across the dried film as compared to a lower viscosity formulation.

### Example 2

Example Formulation 2 was prepared as described in Example 1 except that a combination of low molecular weight PEO (Mv=100,000) and high molecular weight PEO (Mv=8,000,000) was used. The low Mv PEO:high Mv PEO weight ratio was 90:10. The viscosity of the formulation was 6.6 cP.

For the purpose of comparison, Comparative Formulation 2 was prepared wherein the low and high Mv PEO electrolytes were replaced with a single polyelectrolyte having a Mv value of 300,000. The comparative formulation had a viscosity of 6.7 cP.

Films were formed from the two compositions. The film was dried at 120° C.

The surface roughness of the films (Ra) was measured using a Veeco Nano scope—V AFM system used in tapping mode.

Ra of the film formed using Example Formulation 2 was 24 nm.

Ra of the film formed using Comparative Formulation 2 was 33 nm.

Without wishing to be bound by any theory, it is believed that higher molecular weight polymers may result in greater surface roughness.

In this case, using a mixture of a majority of a low molecular weight polymer with a minority of a high molecular weight polymer (in this case, 90 weight % of 100,000 Mv polymer and 10 weight % of 8,000,000 Mv polymer), a smoother film is obtained than using only a single polymer of intermediate Mv (in this case, 300,000 Mv polymer only) to achieve a desired formulation viscosity.

Although the present invention has been described in terms of specific exemplary embodiments, it will be appreciated that various modifications, alterations and/or combinations of features disclosed herein will be apparent to those skilled in the art without departing from the scope of the invention as set forth in the following claims.

1. A composition comprising a low molecular weight polyelectrolyte, a high molecular weight polymer, a light-emitting material and a salt, wherein the viscosity average molecular weight of the high molecular weight polymer in at least one solvent is at least 5 times greater than the viscosity average molecular weight of the low molecular weight polyelectrolyte in the at least one solvent.

2. The composition according to claim 1, wherein the viscosity average molecular weight of the high molecular weight polymer is at least 10 times greater than the viscosity average molecular weight of the low molecular weight polyelectrolyte.

3. The composition according to claim 1, wherein the high molecular weight polymer is a polyelectrolyte.

4. The composition according to claim 3, wherein the high molecular weight polymer and the low molecular weight polymer are different molecular weight polymers of the same polyelectrolyte material.

5. The composition according to claim 1, wherein the high molecular weight polymer is not a polyelectrolyte.

6. The composition according to claim 1, wherein the low molecular weight polyelectrolyte is polyethylene oxide.

7. The composition according to claim 1, wherein the high molecular weight polymer:low molecular weight polyelectrolyte weight ratio is in the range of 1:99 to 40:60.

8. A composition according to claim 1, wherein the light-emitting material is a polymer, or wherein the light-emitting material is a non-polymeric dopant doped in a polymeric host.

9. A method for preparation of a composition according to claim 1, comprising the step of mixing the high molecular weight polymer with the low molecular weight polyelectrolyte.

10. A composition obtainable by the method according to claim 9.

11. A formulation comprising a composition according to claim 1, and the at least one solvent.

12. A formulation according to claim 11, wherein the formulation comprises only one solvent.

13. A formulation according to claim 11, wherein the low molecular weight polyelectrolyte, a high molecular weight polymer, a light-emitting material and salt together form 0.2-10 weight % of the formulation.

14. A light-emitting electrochemical cell comprising an anode for injecting positive charge carriers, a cathode for injecting negative charge carriers and a light-emitting layer between the anode and the cathode wherein the light-emitting layer comprises a composition according to claim 1.

15. A method of forming a light-emitting electrochemical cell according to claim 14, the method comprising the steps of:
(i) depositing the formulation comprising a low molecular weight polyelectrolyte, a high molecular weight polymer, a light-emitting material and a salt, wherein the viscosity average molecular weight of the high molecular weight polymer in at least one solvent is at least 5 times greater than the viscosity average molecular weight of the low molecular weight polyelectrolyte in the at least one solvent and at least one solvent over one of the anode and cathode;
(ii) evaporating the at least one solvent; and
(iii) forming the other of the anode and cathode over the light-emitting layer.

16. A method according to claim 15 wherein the formulation is deposited by a method selected from nozzle printing, screen printing, gravure printing, inkjet printing, nozzle printing, spin-coating, dip-coating, slot die coating and bar-coating.

17. A method according to claim 16, wherein the formulation is deposited by nozzle printing.

18. A light-emitting composition comprising a polyelectrolyte, a light-emitting material, a polymer comprising dialkylsiloxane repeat units and a salt.

19. A light-emitting composition according to claim 18 wherein the dialkylsiloxane repeat units are dimethylsiloxane repeat units.

20. A light-emitting composition according to claim 18 wherein the polymer is a dialkylsiloxane-ethylene oxide copolymer.
